(19) United States
(12) Patent Application Publication
(10) Pub. No.: US 2021/0328147 A1
(43) Pub. Date: Oct. 21, 2021

(54) CARRIER FOR SUPPORTING A SUBSTRATE OR A MASK

(71) Applicant: Applied Materials, Inc., Santa Clara, CA (US)

(72) Inventors: Tommaso VERCESI, Aschaffenburg (DE); Matthias HEYMANNS, Münster (DE)

(21) Appl. No.: 16/340,372

(22) PCT Filed: Apr. 3, 2018
(86) PCT No.: PCT/EP2018/058467

§ 371 Date: Apr. 8, 2019

(51) Int. Cl. H01L 51/00; C23C 14/56; C23C 14/04; C23C 14/24; C23C 14/50; H01L 51/56

(52) U.S. Cl. CPC H01L 51/0012; C23C 14/564; C23C 14/042; H01L 51/56; C23C 14/50; H01L 51/001; H01L 51/0011; C23C 14/24

(57) ABSTRACT

A carrier for supporting a substrate or a mask in a vacuum chamber in or parallel to a first plane is provided. The carrier comprises a clamping device for fixing the carrier to an aligning device and a mechanical motion element connecting the clamping device to the carrier, the mechanical motion element allowing for relative movement of the clamping device and the carrier for at least one degree of freedom and providing a fixed connection between the clamping device and the carrier for at least another degree of freedom.

### FIELD

Embodiments of the present disclosure relate to a carrier for supporting a substrate or a mask in a vacuum chamber, more specifically for supporting said substrate or mask in or parallel to a first plane. Embodiments of the present disclosure further relate to arrangements for adjusting the position of a carrier or a position of a substrate carrier relative to a mask carrier in a processing chamber. Furthermore, the embodiments of the present disclosure relate to an apparatus for depositing a layer on a substrate as well as to a method for adjusting the position of a carrier during a processing in a processing chamber.

### BACKGROUND

Opto-electronic devices that make use of organic materials, such as organic light-emitting diodes (OLED), are becoming increasingly popular for a number of reasons. OLEDs are a special type of light-emitting diode in which the emissive layer includes a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness and viewing angles possible with OLED displays is greater than that of traditional LCD displays because OLED pixels directly emit light and do not involve a back light. The energy consumption of OLED displays is considerably less than that of traditional LCD displays. Further, the fact that OLEDs can be manufactured onto flexible substrates results in further applications.

OLEDs are realized by depositing a material on a substrate. Several methods are known for this purpose. As an example, substrates may be coated by using an evaporation process, a physical vapor deposition (PVD) process, such as a sputtering process, a spraying process, etc., or a chemical vapor deposition (CVD) process. The process can be performed in a processing chamber of a deposition apparatus, where the substrate to be coated is located. A deposition material is provided in the processing chamber. The particles can for example pass through a mask having a boundary or a specific pattern to deposit material at desired positions on the substrate, e.g. to form an OLED pattern on the substrate. A plurality of materials, such as organic material, molecules, metals, oxides, nitrides, and carbides may be used for deposition on a substrate. Further, other processes like etching, structuring, annealing, or the like can be conducted in processing chambers.

For example, coating processes may be considered for large area substrates, e.g. in display manufacturing technology. Coated substrates can be used in several applications and in several technical fields. For instance, an application can be organic light emitting diode (OLED) panels. Further applications include insulating panels, microelectronics, such as semiconductor devices, substrates with thin film transistors (TFTs), color filters, or the like. OLEDs are solid-state devices composed of thin films of (organic) molecules that create light with the application of electricity. As an example, OLED displays can provide bright displays on electronic devices and use reduced power compared to, for example, liquid crystal displays (LCDs). In the processing chamber, the organic molecules are generated (e.g., evaporated, sputtered, or sprayed etc.) and deposited as layer on the substrates. The material can for example pass through a mask having a boundary or a specific pattern to deposit material at desired positions on the substrate, e.g. to form an OLED pattern on the substrate.

An aspect related to the quality of the processed substrate, in particular of the deposited layer, is the alignment of the substrate with respect to the mask. As an example, the alignment should be accurate and repeatable in order to achieve good process results. Accordingly, devices are used—which are coupled to the substrate and/or the mask carrier—for aligning the substrate relative to the mask. The alignment devices may suffer when providing an accurate alignment of the substrate relative to the mask, especially in some particular directions.

In view of the above, there is a need for carriers, arrangements, apparatuses and methods, which can provide for fine adjusting movements of the carrier in different directions.

### SUMMARY

According to an embodiments, a carrier for supporting a substrate or a mask in a vacuum chamber in or parallel to a first plane is provided. The carrier includes a clamping device for fixing the carrier to an aligning device; and a mechanical motion element connecting the clamping device to the carrier, the mechanical motion element allowing for relative movement of the clamping device and the carrier for at least one degree of freedom and providing a fixed connection between the clamping device and the carrier for at least another degree of freedom.

According to another embodiment, an arrangement for adjusting the position of a carrier during a processing in a processing chamber is provided. The arrangement includes a holding device for supporting the carrier in or parallel to a first plane; an aligning device for moving the carrier according at least to a linear direction in or parallel to said first plane; a clamping device for fixing the aligning device to the carrier; and a mechanical motion element connecting the clamping device to the carrier, the mechanical motion element allowing for relative movement of the clamping device and the carrier for at least one degree of freedom and providing a fixed connection between the clamping device and the carrier for at least another degree of freedom.

According to another embodiment, an arrangement for adjusting the position of a substrate carrier relative to a mask carrier during a processing in a processing chamber is provided. The arrangement includes a holding device for supporting the substrate carrier in or parallel to a first plane; an aligning device for moving the substrate carrier and the mask carrier relative to each other according at least to a linear direction in or parallel to the first plane; a clamping device for fixing the aligning device to the substrate carrier and/or the mask carrier; and a mechanical motion element connecting the clamping device to the substrate carrier and/or the mask carrier, the mechanical motion element allowing for relative movement of the clamping device and the substrate carrier and/or the mask carrier for at least one degree of freedom and providing a fixed connection between the clamping device and the substrate carrier and/or the mask carrier for at least another degree of freedom.

According to another embodiment an apparatus for depositing a layer on a substrate is provided. The apparatus includes a processing chamber adapted for layer deposition therein; an arrangement according to any one of embodiments described herein for a carrier within the processing chamber, and a deposition source for depositing material forming the layer.

According to another embodiment, a method for adjusting the position of a carrier during a processing in a processing chamber is provided. The method includes supporting the carrier in or parallel to a first plane; fixing an aligning device to the carrier through a clamping device; and allowing for relative movement of the clamping device and carrier for at least one degree of freedom and providing a fixed connection between the clamping device and the carrier for at least another degree of freedom.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a deposition process for manufacturing OLEDs on a substrate;

FIG. 2A shows a schematic front view of a holding arrangement for supporting a substrate and a mask in a vertical orientation during layer deposition in a processing chamber;

FIG. 2B shows a schematic side view of the holding arrangement of FIG. 2A;

FIG. 3 shows a schematic view of a holding arrangement for supporting a substrate carrier and/or a mask carrier during layer deposition in a processing chamber;

FIG. 4 shows a schematic representation of a carrier for supporting a substrate or a mask according to an embodiment of the present disclosure;

FIG. 5 shows a detail of the carrier in FIG. 4 in a perspective view;

FIG. 6 shows a schematic representation of an arrangement for adjusting the position of a carrier according to an embodiment of the present disclosure;

FIG. 7 shows a schematic representation of an arrangement for adjusting the position of a substrate carrier relative to a mask carrier according to an embodiment of the present disclosure;

FIG. 8 shows a schematic representation of an apparatus for depositing a layer on a substrate according to an embodiment of the present disclosure; and

FIG. 9 shows a flow chart of a method for adjusting the position of a carrier during a processing in a processing chamber according to an embodiment of the present disclosure.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on, or in conjunction with, other embodiments to yield yet a further embodiment. It is intended that the description includes such modifications and variations.

The embodiments described herein can be utilized for inspecting large area coated substrates, e.g., for manufactured displays. The substrates or substrate receiving areas for which the apparatuses and methods described herein are configured can be large area substrates having a size of e.g. 1 m² or above. For example, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. For example, for OLED display manufacturing, half sizes of the above mentioned substrate generations, including GEN 6, can be coated by evaporation of an apparatus for evaporating material. The half sizes of the substrate generation may result from some processes running on a full substrate size, and subsequent processes running on half of a substrate previously processed.

The term “substrate” as used herein may particularly embrace substantially inflexible substrates, e.g., a wafer, slices of transparent crystal such as sapphire or the like, or a glass plate. However, the present disclosure is not limited thereto and the term “substrate” may embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates.

A substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials, metal or any other material or combination of materials which can be coated by a deposition process.

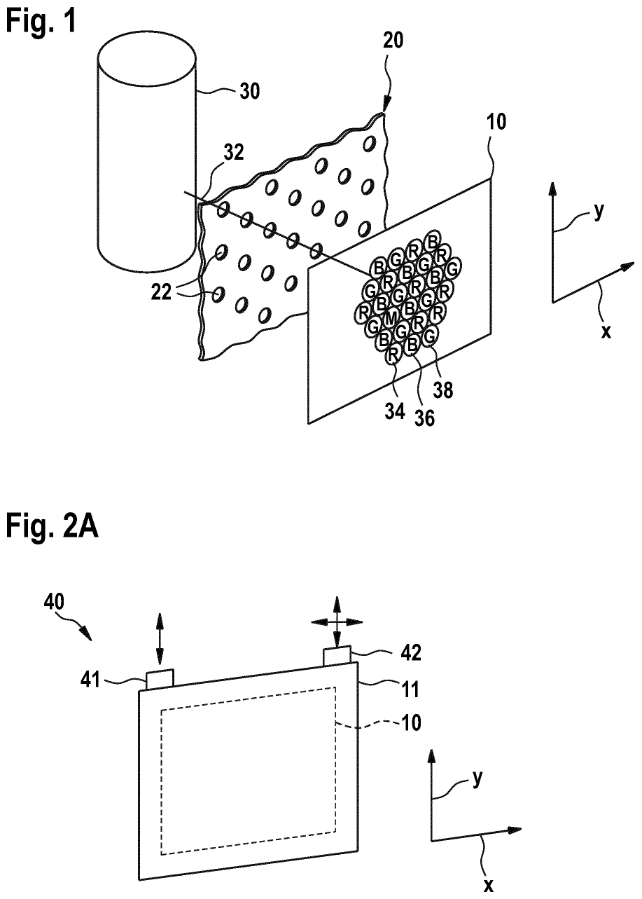

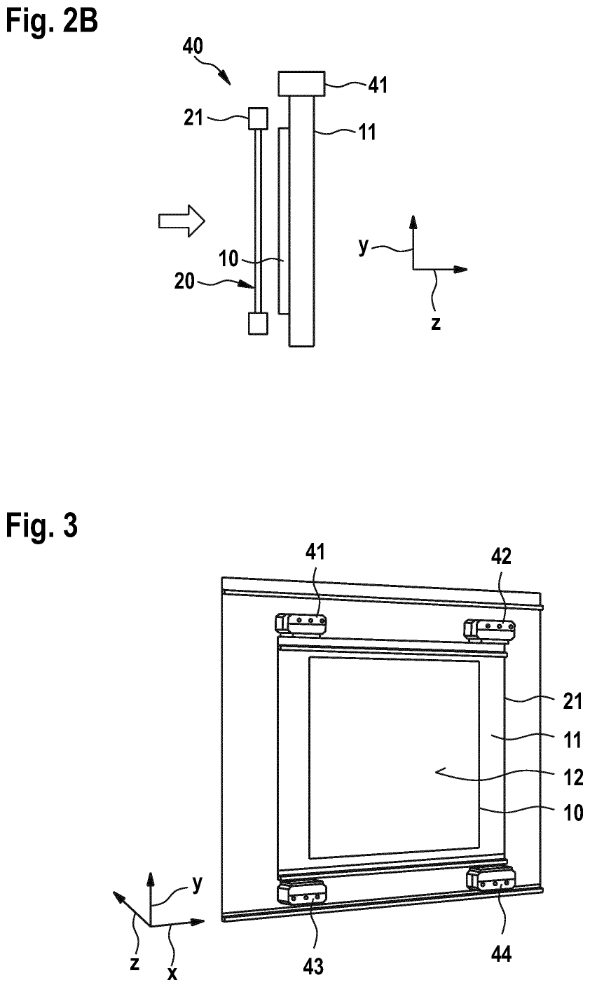

FIG. 1 shows a schematic view of a deposition process for manufacturing OLEDs on a substrate 10, whereas FIGS. 2A and 2B show an example of an holding arrangement 40 for supporting a substrate 10 on a substrate carrier 11 and a mask 20 on a mask carrier 21 during layer deposition in a processing chamber, wherein the substrate 10 and the mask 20 are maintained in an essentially vertical position.

As shown in FIG. 1, for manufacturing OLEDs, organic molecules can be provided by a deposition source 30 (e.g., evaporated) and deposited on the substrate 10. A mask arrangement including a mask 20 is positioned between the substrate 10 and the deposition source 30. The mask 20 has a specific pattern, e.g., provided by a plurality of openings or holes 22, so that organic molecules pass through the openings or holes 22 (e.g., along a path 32) to deposit a patterned layer or film of an organic compound on the substrate 10. A plurality of layers or films can be deposited on the substrate 10 using different masks or positions of the mask 20 with respect to the substrate 10, e.g., to generate pixels, for example, with different color properties. As an example, a first layer or film can be deposited to generate red pixels 34, a second layer or film can be deposited to generate green pixels 36, and a third layer or film can be deposited to generate blue pixels 38. The layer(s) or film(s), e.g., an organic material, can be arranged between two electrodes, such as an anode and a cathode (not shown). At least one electrode of the two electrodes can be transparent.

The substrate 10 and the mask 20 can be arranged in a vertical orientation, or a substantially vertical orientation, during the deposition process. In FIG. 1, arrows indicate a vertical direction Y and a horizontal direction X. As used throughout the present disclosure, the term “vertical direction” or “vertical orientation” is understood to distinguish over “horizontal direction” or “horizontal orientation”. That is, the “vertical direction” or “vertical orientation” relates to a substantially vertical orientation e.g. of the holding arrangement and the substrate, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

FIG. 2A shows a schematic view of a holding arrangement 40 for supporting a substrate carrier 11 and a mask carrier 21 during layer deposition in a processing chamber that can be used in systems and apparatuses according to embodiments described herein. FIG. 2B shows a side view of the holding arrangement 40 shown in FIG. 2A.

Alignment systems used on vertical-operated tools can work from outside of a processing chamber, i.e., from the atmospheric side. The alignment system can be connected to a substrate carrier and a mask carrier with stiff arms, e.g., extending through a wall of the processing chamber. For an alignment system outside of the vacuum, a mechanical path between mask carrier or mask and substrate carrier or substrate is long, making the system susceptible to external interference (vibrations, heating, etc.) and tolerances.

Additionally or alternatively, an actuator of an alignment system may be included within the vacuum chamber. Accordingly, a length of a stiff arm may be reduced. For example, an actuator that may mechanically contact the substrate carrier and the mask carrier can be at least partially provided between a track for the mask carrier and a track for the substrate carrier.

The holding arrangement 40 may include two or more alignment actuators connectable to at least one of the substrate carrier 11 and the mask carrier 21, wherein the holding arrangement 40 is configured to support the substrate carrier 11 in or parallel to, a first plane, wherein a first alignment actuator 41 of the two or more alignment actuators may be configured to move the substrate carrier 11 and the mask carrier 21 relative to each other at least in a first direction Y, wherein a second alignment actuator 42 of the two or more alignment actuators may be configured to move the substrate carrier 11 and the mask carrier 21 relative to each other at least in the first direction Y and a second direction X different from the first direction Y, and wherein the first direction Y and the second direction X are in the first plane. The two or more alignment actuators can also be referred to as “alignment blocks”. Accordingly, the alignment blocks or alignment actuators can change the position of the substrate 10 and the mask 20 relative to each other. For example, an alignment block can be constituted by a first element fixed to the substrate carrier 11 or mask carrier 21 and a second element fixed to an alignment device provided with one or more actuators. The first element can be clamped to the second element through a mutual interaction (i.e. mechanical, magnetic, electromagnetic, etc.).

As shown in FIG. 2B, the mask 20 can be attached to the mask carrier 21 and the holding arrangement 40 is configured for supporting at least one of the substrate carrier 11 and the mask carrier 21, particularly both, the substrate carrier 11 and the mask carrier 21, in a substantially vertical orientation, in particular during layer deposition. The deposition occurs along the direction Z according to the arrow illustrated in FIG. 2B.

By moving the substrate carrier 11 and the mask carrier 21 relative to each other at least in the first direction Y and the second direction X using the two or more alignment actuators, the substrate carrier 11 can be aligned with respect to the mask carrier 21 or mask 20, and the quality of the deposited layers can be improved.

For performing an adjustment of the position of the mask 20 relative to the substrate 10, by actuation of the alignment blocks, an optical inspection can also be performed in order to check possible variances or deviations relative to a correct alignment.

The two or more alignment actuators can be connectable to at least one of the substrate carrier 11 and the mask carrier 21. As an example, the two or more alignment actuators are connectable to the substrate carrier 11, wherein the two or more alignment actuators are configured to move the substrate carrier 11 relative to the mask carrier 21. The mask carrier 21 can be in a fixed or stationary position. In other examples, the two or more alignment actuators are connectable to the mask carrier 21, wherein the two or more alignment actuators are configured to move the mask carrier 21 relative to the substrate carrier 11. The substrate carrier 11 can be in a fixed or stationary position. In other examples, the two or more alignment actuators are connectable to the mask carrier 21 and the substrate carrier 11, wherein the two or more alignment actuators are configured to move the mask carrier 21 and the substrate carrier 11 relative to reach other.

In the holding arrangement of FIG. 3, the two or more alignment actuators include at least one of a third alignment actuator 43 and a fourth alignment actuator 44. The holding arrangement can have four alignment actuators, e.g., first alignment actuator 41, the second alignment actuator 42, the third alignment actuator 43, and the fourth alignment actuator 44. As an example, two or more alignment actuators can be situated on corners or in corner regions of the substrate carrier 11 (or mask carrier 21).

According to some embodiments, which can be combined with other embodiments described herein, a first direction and a second direction can define or span a plane and can in particular define or span the first plane. As used throughout the present disclosure, the term “plane” can refer to a flat, two-dimensional surface. Yet, further, the alignment actuators may also move the substrate carrier and the mask carrier relative to each other in a third direction, e.g. the z-direction in FIG. 3, wherein the third direction may be orthogonal to the plane.

As used throughout the present disclosure, the term “direction” can refer to information contained in the relative position of one point with respect to another point. The direction may be specified by a vector. As an example, the first direction can correspond to a first vector, and the second direction can correspond to a second vector. The first direction or first vector and the second direction or second vector can be defined using a coordinate system, for example, a Cartesian coordinate system. According to the embodiments described herein, the second direction is different from the first direction. In other words, the second direction is neither parallel nor antiparallel to the first direction. As an example, the first vector and the second vector can point in different directions.

In some embodiments, the first direction and the second direction are substantially perpendicular to each other. As an example, the first direction and the second direction can define the first plane in the coordinate system, for example, the Cartesian coordinate system. In some implementations, the first direction can be referred to as “y-direction”, and the second direction can be referred to as “x-direction”.

According to embodiments described herein, which can be combined with other embodiments described herein, the first direction (y-direction) can correspond to the vertical direction relating to the substantially vertical orientation e.g. of the holding arrangement and the substrate (indicated with Y in FIG. 1). In some implementations, the second direction (x-direction) can correspond to a horizontal direction (indicated with X in FIG. 1).

In some implementations, at least one alignment actuator of the two or more alignment actuators is configured to move the substrate carrier 11 and the mask carrier 21 relative to each other in a third direction, in particular wherein the third direction is substantially perpendicular to the first plane and/or a substrate surface. As an example, the first alignment actuator 41 and the second alignment actuator 42 are configured to move the substrate carrier 11 or mask carrier 21 in the third direction. The third direction can for example be referred to as “z-direction”. According to some embodiments, at least one of the third alignment actuator 43 and the fourth alignment actuator 44 is configured to move the substrate carrier 11 or mask carrier 21 in the third direction, e.g., substantially perpendicular to the substrate surface. In some embodiments, at least one alignment actuator of the third alignment actuator 43 and the fourth alignment actuator 44 is not configured to actively move the substrate carrier 11 in the first direction and/or the second direction. The at least one alignment actuator of the third alignment actuator 43 and the fourth alignment actuator 44 is configured to move the substrate carrier only in the third direction.

In some implementations, a distance between the substrate 10 and the mask 20 can be adjusted by moving the substrate carrier 11 or the mask carrier 21 in the third direction.

According to some embodiments, which can be combined with other embodiments described herein, the first alignment actuator 41 is floating with respect to the second direction. The term “floating” may be understood as the first alignment actuator 41 allowing a movement of the substrate carrier 11 in the second direction, e.g., driven by the second alignment actuator 42. As an example, the first alignment actuator 41 is configured to actively move the substrate carrier 11 in the first direction, and is configured to passively allow a movement of the substrate carrier 11 in the second direction. In some implementations, the term “floating” may be understood as “freely moveable”. As an example, the first alignment actuator 41 can allow a free movement of the substrate carrier 11 in the second direction. In other words, the first alignment actuator 41 does not hinder (or interfere with) a movement of the substrate carrier 11 in the second direction, e.g., when the second alignment actuator 42 is driven.

According to some embodiments, which can be combined with other embodiments described herein, at least one alignment actuator of the third alignment actuator 43 and the fourth alignment actuator 44 is floating with respect to the first direction and the second direction. As an example, at least one alignment actuator of the third alignment actuator 43 and the fourth alignment actuator 44 is floating with respect to the first plane. In some embodiments, the third alignment actuator 43 and the fourth alignment actuator 44 can be configured to (passively) allow a movement of the substrate carrier 11 or mask carrier 21 in the first direction and the second direction, e.g., driven by the first alignment actuator 41 and/or the second alignment actuator 42.

The holding arrangement is configured to support the substrate carrier 11 in or parallel to, the first plane. In some implementations, the first plane is substantially parallel to a plane of the substrate surface 12 configured for layer deposition thereon. As an example, the substrate surface 12 can be an extended surface of the substrate 10 on which one or more layers are to be deposited. The substrate surface 12 can also be referred to as “processing surface of the substrate”. The third direction can be substantially perpendicular to or normal to the substrate surface 12. According to some embodiments, which can be combined with other embodiments described herein, the substrate carrier 11 supporting the substrate 10 is moveable using the two or more alignments actuators substantially parallel to the first plane in at least one of the first direction and the second direction, and in particular substantially parallel to the substrate surface 12. Also, the substrate carrier 11 is movable substantially perpendicular to the substrate surface 12 in the third direction.

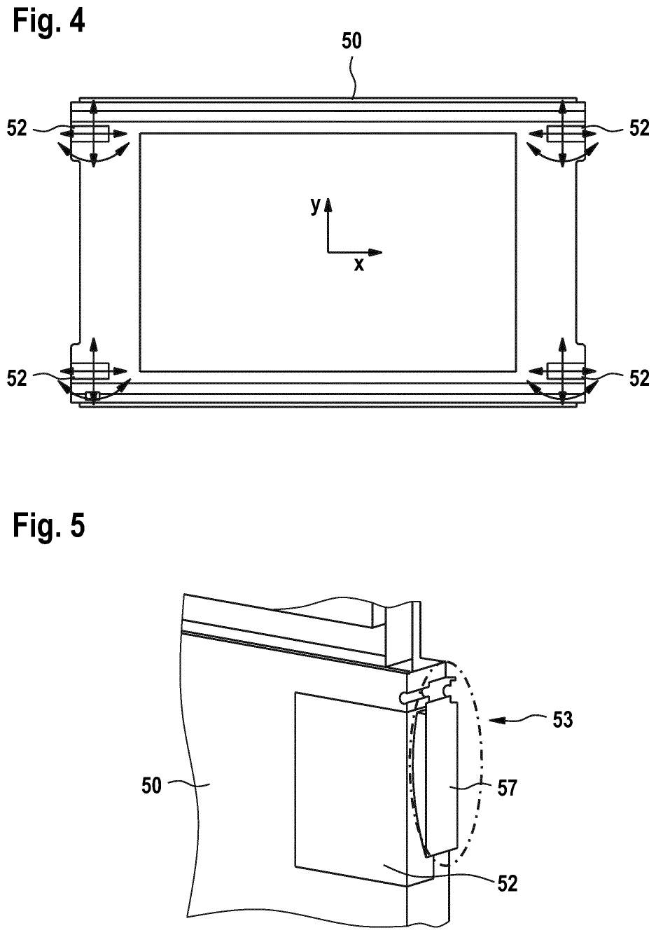

FIG. 4 describes a carrier 50 for supporting a substrate 10 or a mask 20 according to one embodiment of the present disclosure. The substrate 10 or the mask 20 are supported in or parallel to a first plane, i.e. the plane XY in the figure. The carrier 50 includes a clamping device for fixing the carrier 50 to an external device, such as an aligning device (not shown in the figure). The clamping device includes at least a first element or first clamping element 52 fixed to the carrier 50. In particular, the carrier 50 may include four first clamping elements 52 located at or adjacent to the corners of the carrier 50, as shown in the figure. These first clamping elements 52 may be each associated with or part of an aligning block as described above, i.e. may be connected to an alignment device. Accordingly, the carrier can be movable in a first direction (y-direction) and/or in a second direction (x-direction). The carrier 50 may also be movable in a third direction (z-direction) perpendicular to the first plane.

FIG. 5 shows a more detailed view of the carrier 50 of FIG. 4, e.g. on the top, right side, of the carrier 50. According to embodiments described herein, a carrier includes at least a mechanical motion element 53 connecting the clamping device (the first clamping element 52) to the carrier 50. The mechanical motion element 53 allows for relative movement of the clamping device and the carrier 50 for at least one degree of freedom and providing a fixed connection between the clamping device and the carrier 50 for at least another degree of freedom. In particular, the carrier 50 may include four mechanical motion elements 53 each connecting a clamping device (each first clamping element 52) to the carrier 50.

According to some embodiments, which can be combined with other embodiments described herein, the mechanical motion element 53 includes an angular positioning device coupled to the clamping device (the first clamping element 52) for moving the carrier 50 in an angular direction around an axis perpendicular to the first plane (i.e. the plane XY). This is shown by the curved double arrows in FIG. 4. In other words, in addition of being movable substantially parallel to the first plane in at least one of the first direction and the second direction (and eventually perpendicular to the first plane in the third direction), the carrier 50 is also movable in an angular direction. This makes the alignment process more accurate and improves the quality of the processed substrate.

According to some embodiments, which can be combined with other embodiments described herein, the mechanical motion element 53 includes one or more hinges 57, wherein a first portion of each hinge 57 is connectable to the carrier 50 through first connection means and a second portion of each hinge 57 is connectable to the clamping device through second connection means. The first and the second connection means may include each for example two or more screws, pins, or the like, insertable in corresponding holes or cavities.

In order to allow the movement of the carrier 50 in the angular direction around an axis perpendicular to the first plane, according to some embodiments, which can be combined with other embodiments described herein, the clamping device (the first clamping element 52) and the mechanical motion element 53 are so configured that the second connection means is rotatable relative to the first connection means. A movement by an angle or an angular movement can be provided between the first connection means and the second connection means.

According to some embodiments, which can be combined with other embodiments described herein, at least a hinge 57 has a high stiffness in a linear direction in or parallel to the first plane and each hinge 57 has a low stiffness in the angular direction around an axis perpendicular to the first plane. According to some embodiments, a hinge can have several degrees of freedom and can be stiff in one or more degrees of freedom and flexible in one or more other degrees of freedom. Typically, the hinge or a mechanical motion element can be flexible in at least two degrees of freedom, e.g. z-direction and rotation, or may be flexible in at least three degrees of freedom, e.g. z-direction, a rotation, and one direction in the plane of the carrier.

According to some embodiments, which can be combined with other embodiments described herein, the carrier 50 includes four hinges 57 located at the corners of the carrier 50. Each hinge 57 is coupled with a corresponding clamping device (with a corresponding first clamping element 52). Referring to FIG. 4, the four hinges 57 are located behind the four first clamping elements 52, at least a portion of each hinge 57 being in contact with a corresponding first clamping element 52. It is noted that the hinges 57 may be configured to have the same shape and dimension of the first clamping elements 52.

For example, the hinge 57 in contact with the first clamping element 52 on the top, left side of the carrier 50 in FIG. 4 can have a high stiffness both in the first and the second directions and can have a low stiffness in the third direction and in the angular direction around an axis perpendicular to the first plane. The hinge 57 in contact with the first clamping element 52 on the top, right side of the carrier 50 in FIG. 4 can have a high stiffness in one direction, e.g. in the first (or the second direction) and can be floating with respect to the second direction (or the first direction). Further, the hinge can have a low stiffness in the third direction and in the angular direction around an axis perpendicular to the first plane). The hinges 57 in contact with the first clamping elements 52 on the bottom, left and right side of the carrier 50 in FIG. 4 can have a low stiffness in all directions (i.e. the first direction, the second direction, the third direction and the angular direction around an axis perpendicular to the first plane).

According to some embodiments, which can be combined with other embodiments described herein, one type of hinge element or mechanical motion element can be provided for each of the corners of a substrate. A degree of freedom that may be beneficial for alignment may be provided by a floating direction of an actuator as described with respect to FIGS. 2A and 2B. According to some embodiments, which can be combined with other embodiments described herein, two or more types of hinge elements or mechanical motion elements that provide different degrees of freedom can be provided for each of the corners of a substrate. An alignment device can, for example, be provided without a floating direction.

According to some embodiments, which can be combined with other embodiments described herein, the carrier 50 is configured to carry a substrate 10 or a mask 20 in an essentially vertical position.

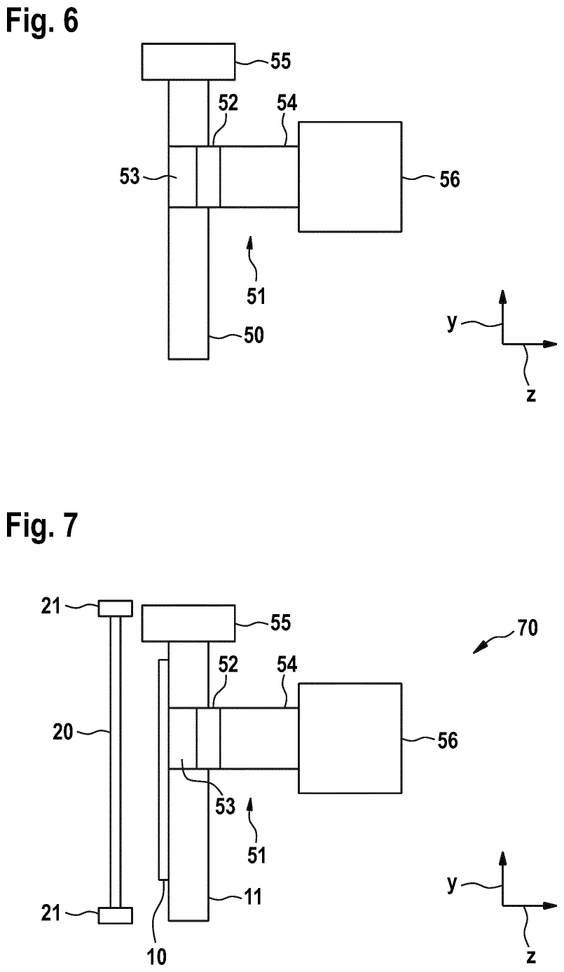

FIG. 6 shows an arrangement 60 for adjusting the position of a carrier 50 during a processing in a processing chamber. The arrangement 60 includes a holding device 55 for supporting the carrier 50 in or parallel to a first plane, for example the XY plane of FIG. 4. The carrier 50 can be configured to carry a substrate 10 or a mask 20 as the substrate carrier 11 or the mask carrier 21 shown in FIG. 2B. It is noted that the arrangement 60 of FIG. 6 is represented in a schematic way on a side view (YZ plane). In addition, the arrangement 60 includes an aligning device 56 for moving the carrier 50 according at least to a linear direction in or parallel to the first plane and a clamping device 51 for fixing the aligning device 56 to the carrier 50. The arrangement 60 further includes a mechanical motion element 53 connecting the clamping device 51 to the carrier 50, the mechanical motion element 53 allowing for relative movement of the clamping device 51 and the carrier 50 for at least one degree of freedom and providing a fixed connection between the clamping device 51 and the carrier 50 for at least another degree of freedom.

As shown in FIG. 6, the clamping device 51 includes a first clamping element 52 connected to the carrier 50 and a second clamping element 54 connected to the device 56. The first clamping element 52 and the second clamping element 54 are configured to be fixable or clampable with respect to each other. In this way, the mechanical motion element 53 allows for relative movement of the first clamping element 52 and the carrier 50 for at least one degree of freedom and provides a fixed connection between the first clamping element 52 and the carrier 50 for at least another degree of freedom.

FIG. 7 shows an arrangement 70 for adjusting the position of a substrate carrier 11 relative to a mask carrier 21 during a processing in a processing chamber. The arrangement 70 includes a holding device 55 for supporting the carrier 11 in or parallel to a first plane, for example the XY plane of FIG. 4. It is noted that the arrangement 70 of FIG. 7 is represented in a schematic way on a side view (YZ plane). In addition, the arrangement 70 includes an aligning device 56 for moving the substrate carrier 11 relative to the mask carrier 21 along at least a linear direction in or parallel to the first plane and a clamping device 51 for fixing the aligning device 56 to the substrate carrier 11 and/or the mask carrier 21. The arrangement 70 further includes a mechanical motion element 53 connecting the clamping device 51 to the substrate carrier 11 and/or the mask carrier 21, the mechanical motion element allowing for relative movement of the clamping device 51 and the substrate carrier 11 and/or the mask carrier 21 for at least one degree of freedom and providing a fixed connection between the clamping device 51 and the substrate carrier 11 and/or the mask carrier 21 for at least another degree of freedom.

FIG. 7 shows a configuration, wherein the clamping device 51 is only connected to the substrate carrier 11. However, in an alternative configuration, the clamping device 51 can be only connected to the mask carrier 21 or can be connected to both the substrate carrier 11 and the mask carrier 21. FIG. 7 shows the clamping device 51 including a first clamping element 52 connected to the carrier 11 and a second clamping element 54 connected to the device 56. The first clamping element 52 and the second clamping element 54 are configured to be fixable or clampable with respect to each other. In this way, the mechanical motion element 53 allows for relative movement of the first clamping element 52 and the substrate carrier 11 for at least one degree of freedom and proves a fixed connection between the first clamping element 52 and the substrate carrier 11 for at least another degree of freedom.

According to some embodiments, which can be combined with other embodiments described herein, the mechanical motion element 53 includes an angular positioning device coupled to the clamping device 51 (to the first clamping element 52) for moving the carrier 50 in an angular direction around an axis perpendicular to the first plane.

According to some embodiments, which can be combined with other embodiments described herein, the mechanical motion element may include one or more degrees of freedom with a low stiffness and one or more degrees of freedom with a high stiffness. For example, the carrier may, thus, be floating for the direction(s) of low stiffness and may be aligned (move) in the direction(s) of high stiffness. The system is not mechanically overdefined and/or tension on a substrate or a mask due to alignment can be avoided or reduced. According to some embodiments, the mechanical motion element can be provided by wire-cutting and/or milling, i.e. cutting and/or milling a structure combining the low and high stiffness in different directions.

According to some embodiments, which can be combined with other embodiments described herein, the clamping device 51 includes a first clamping element 52 coupled to the carrier 50 and a second clamping element 54 coupled to the aligning device 56. The first clamping element 52 can include at least a magnetic plate and the second clamping element 54 can include at least an electro-permanent magnet.

According to some embodiments, which can be combined with other embodiments described herein, the aligning device 56 is further configured for moving the carrier 50 according to a direction perpendicular to the first plane (i.e. in the z-direction).

Based on the arrangement configurations described above, the generic term “carrier” 50 can be referred to a “substrate carrier” 11 or a “mask carrier” 21.

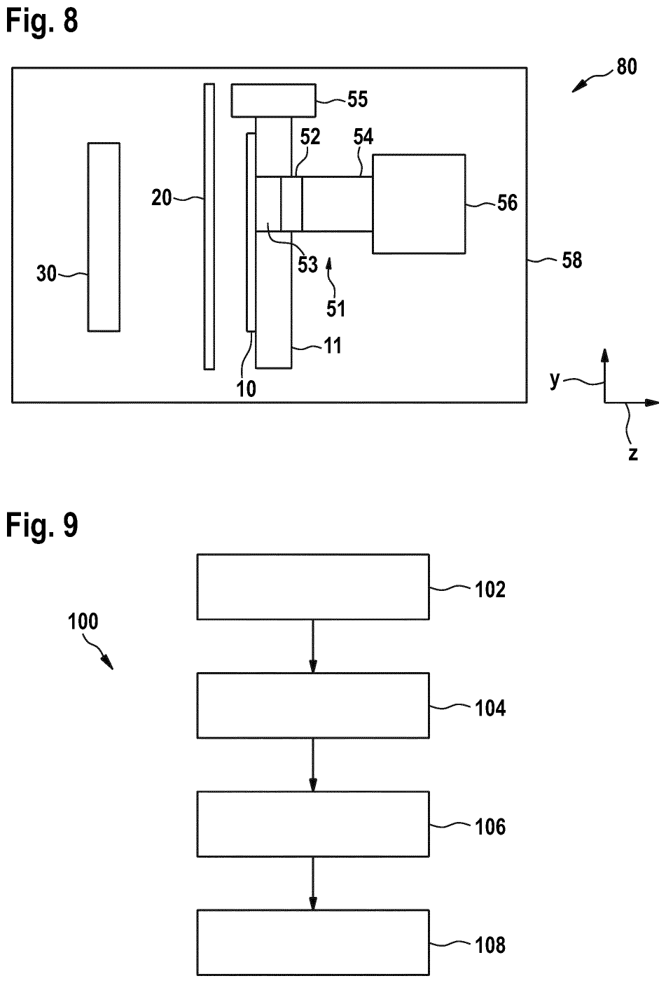

FIG. 8 describes an apparatus 80 for depositing a layer on a substrate 10. The apparatus 80 includes a processing chamber 58 adapted for layer deposition therein, an arrangement 60, 70 for a carrier 50, 11 within the processing chamber according to any one of embodiments described above and a deposition source 30 for depositing material forming the layer.

The use of the arrangements 60, 70 described above in the apparatus 80 are beneficial for adjusting the position of the carrier 50 (specifically of the substrate carrier 11 and/or the mask carrier 21) in a more precise way and along different directions. Advantageously, the carrier 50 (specifically the substrate carrier 11 and/or the mask carrier 21) can be moved along the first direction (y-direction), the second direction (x-direction) the third direction (z-direction) and in an angular direction around an axis parallel to the third direction (z-direction). This leads to an improved quality of the deposited layer on the substrate 10.

FIG. 9 describes a method 100 for adjusting the position of a carrier 50 (specifically of the substrate carrier 11 and/or the mask carrier 21) during a processing in a processing chamber. The method 100 includes supporting 102 the carrier 50 in or parallel to a first plane, for example the XY plane of FIG. 4 and fixing 104 an aligning device 56 to the carrier 50 through a clamping device 51. The method 100 furthermore includes allowing 106 for relative movement of the clamping device 51 and carrier 50 for at least one degree of freedom and providing 108 a fixed connection between the clamping device 51 and the carrier 50 for at least another degree of freedom.

The clamping device 51 can include a first clamping element 52 connected to the carrier 50 and a second clamping element 54 connected to the device 56, first clamping element 52 and the second clamping element 54 being configured to be fixable or clampable with respect to each other. In this way, the method 100 includes allowing 106 for relative movement of the first clamping element 52 and carrier 50 for at least one degree of freedom and providing 108 a fixed connection between the first clamping element 52 and the carrier 50 for at least another degree of freedom.

According to some embodiments, which can be combined with other embodiments described herein, the method 100 includes moving the carrier 50 in an angular direction around an axis perpendicular to the first plane. In this way the position of the carrier 50 (specifically of the substrate carrier 11 and/or the mask carrier 21) can be adjusted in a more precise way and along different directions. Advantageously, the method 100 allows for moving the carrier 50 (specifically the substrate carrier 11 and/or the mask carrier 21) along the first direction (y-direction), the second direction (x-direction) the third direction (z-direction) and in an angular direction around an axis parallel to the third direction (z-direction). This leads to an improved quality of the deposited layer on the substrate 10.

According to some embodiments, which can be combined with other embodiments described herein, the carrier 50 is configured to carry a substrate 10 or a mask 20 in an essentially vertical position.

The embodiments according to the present disclosure have several advantages including the possibility of adjusting the position of the carrier 50 (and specifically of the substrate carrier 11 and/or the mask carrier 21) more accurately. The carrier 50 can be moved along the first direction (y-direction), the second direction (x-direction) the third direction (z-direction) and in an angular direction around an axis parallel to the third direction (z-direction).

While the foregoing is directed to embodiments of the disclosure, other and further embodiments of the disclosure may be devised without departing from the basic scope thereof, and the scope thereof is determined by the claims that follow.

1. A carrier for supporting a substrate or a mask in a vacuum chamber in or parallel to a first plane, the carrier comprising:
a clamping device for fixing the carrier to an aligning device; and
a mechanical motion element connecting the clamping device to the carrier, the mechanical motion element allowing for relative movement of the clamping device and the carrier for at least one degree of freedom and providing a fixed connection between the clamping device and the carrier for at least another degree of freedom.

2. The carrier according to claim 1, wherein the mechanical motion element comprises an angular positioning device coupled to the clamping device for moving the carrier in an angular direction around an axis perpendicular to the first plane.

3. The carrier according to claim 1, wherein the mechanical motion element comprises one or more hinges, a first portion of each hinge being connectable to the carrier through first connection means and a second portion of each hinge being connectable to the clamping device through second connection means.

4. The carrier according to claim 3, wherein the mechanical motion element is configured to allow angular movement of the second connection means relative to the first connection means and vice versa.

5. The carrier according to claim 3, wherein the first and the second connection means each comprise one or more holes.

6. The carrier according to any claim 3, wherein at least a hinge of the one or more hinges has a high stiffness in a linear direction in or parallel to the first plane and each hinge has a low stiffness in the angular direction around an axis perpendicular to the first plane.

7. The carrier according to any claim 1, wherein the carrier is configured to carry a substrate or a mask in an essentially vertical position.

8. An arrangement for adjusting the position of a carrier during a processing in a processing chamber, the arrangement comprising:
a holding device for supporting the carrier in or parallel to a first plane;
an aligning device for moving the carrier according at least to a linear direction in or parallel to said first plane;
a clamping device for fixing the aligning device to the carrier; and
a mechanical motion element connecting the clamping device to the carrier, the mechanical motion element allowing for relative movement of the clamping device and the carrier for at least one degree of freedom and providing a fixed connection between the clamping device and the carrier for at least another degree of freedom.

9. An arrangement for adjusting the position of a substrate carrier relative to a mask carrier during a processing in a processing chamber, the arrangement comprising:
a holding device for supporting the substrate carrier in or parallel to a first plane;
an aligning device for moving the substrate carrier and the mask carrier relative to each other according at least to a linear direction in or parallel to the first plane;
a clamping device for fixing the aligning device to at least one of the substrate carrier and the mask carrier; and
a mechanical motion element connecting the clamping device to at least one of the substrate carrier and the mask carrier, the mechanical motion element allowing for relative movement of the clamping device and at least one of the substrate carrier and the mask carrier for at least one degree of freedom and providing a fixed connection between the clamping device and at least one of the substrate carrier and the mask carrier for at least another degree of freedom.

10. The arrangement according claim 9, wherein the mechanical motion element comprises an angular positioning device coupled to the clamping device for moving the carrier in an angular direction around an axis perpendicular to the first plane.

11. The arrangement according to claim 9, wherein the clamping device comprises a first clamping element coupled to the carrier and a second clamping element coupled to the aligning device, the first clamping element comprising at least a magnetic plate and the second clamping element comprising at least an electro-permanent magnet.

12. The arrangement according to claim 8, wherein the aligning device is further configured for moving the carrier along a direction perpendicular to the first plane.

13. An apparatus for depositing a layer on a substrate, comprising:
a processing chamber adapted for layer deposition therein;
an arrangement for a carrier within the processing chamber, the arrangement comprising:
a holding device for supporting the carrier in or parallel to a first plane;
an aligning device for moving the carrier according at least to a linear direction in or parallel to said first plane;
a clamping device for fixing the aligning device to the carrier; and
a mechanical motion element connecting the clamping device to the carrier, the mechanical motion element allowing for relative movement of the clamping device and the carrier for at least one degree of freedom and providing a fixed connection between the clamping device and the carrier for at least another degree of freedom, and
a deposition source for depositing material forming the layer.

14. A method for adjusting the position of a carrier during a processing in a processing chamber, the method comprising:
supporting the carrier in or parallel to a first plane;
fixing an aligning device to the carrier through a clamping device; and
allowing for relative movement of the clamping device and carrier for at least one degree of freedom and providing a fixed connection between the clamping device and the carrier for at least another degree of freedom.

15. The method according to claim 14, further including:
moving the carrier in an angular direction around an axis perpendicular to the first plane.

16. The method according to 15, wherein the carrier is configured to carry a substrate or a mask in an essentially vertical position.

17. The carrier according to claim 2, wherein the mechanical motion element comprises one or more hinges, a first portion of each hinge being connectable to the carrier through first connection means and a second portion of each hinge being connectable to the clamping device through second connection means.

18. The carrier according to claim 4, wherein the mechanical motion element is configured to allow angular movement of the second connection means relative to the first connection means and vice versa.

19. The arrangement according to claim 9, wherein the mechanical motion element comprises an angular positioning device coupled to the clamping device for moving the carrier in an angular direction around an axis perpendicular to the first plane.

20. The arrangement according to claim 9, wherein the clamping device comprises a first clamping element coupled to the carrier and a second clamping element coupled to the aligning device, the first clamping element comprising at least a magnetic plate and the second clamping element comprising at least an electro-permanent magnet.
